(19) United States
(12) Patent Application Publication
(10) Pub. No.: US 2026/0113887 A1
(43) Pub. Date: Apr. 23, 2026

(54) ELECTRONIC CONTROL DEVICE

(71) Applicant: HYUNDAI MOBIS CO., LTD., Seoul (KR)

(72) Inventors: Hyun Seong LEE, Yongin-si (KR); Seong Hyeon PARK, Yongin-si (KR); Sung Bae JEON, Yongin-si (KR); Sun Jong OH, Yongin-si (KR); Sung Min YOO, Yongin-si (KR)

(73) Assignee: HYUNDAI MOBIS CO., LTD., Seoul (KR)

(21) Appl. No.: 19/218,756

(22) Filed: May 27, 2025

(30) Foreign Application Priority Data
Oct. 22, 2024 (KR) 10-2024-0145196

(51) Int. Cl. H05K 7/20

(52) U.S. Cl. CPC H05K 7/2039

(57) ABSTRACT

An electronic control device includes a base part including a base plate, a panel part including a panel body disposed on a front of the base part and a panel body coupling hole communicating a first side of the panel body with a second side of the panel body, and a heat dissipation part including a heat dissipation body disposed on an upper portion of the base part to face the base plate and a heat dissipation coupling protrusion protruding from the heat dissipation body and inserted into the panel body coupling hole.

### CROSS-REFERENCE TO RELATED APPLICATION

This application claims the benefit under 35 U.S.C. § 119(a) of priority to Korean Patent Application No. 10-2024-0145196 filed on Oct. 22, 2024, in the Korean Intellectual Property Office, the entire disclosure of which is incorporated herein by reference for all purposes.

### BACKGROUND

### 1. Technical Field

Exemplary embodiments of the present disclosure relate to an electronic control unit, and more particularly, to an electronic control unit having improved water resistance.

### 2. Related Art

As electronic control technology for automobiles develops, many mechanical components for controlling automobiles are being replaced by electronic control devices. As the components controlled by electronic control devices increase, the heat generated by electronic control units is increasing. As a fan is applied to increase the heat dissipation of the electronic control device, the exterior and interior of the electronic control device communicate with each other, which causes a problem in that the water resistance of the electronic control device is reduced.

Accordingly, there is an increasing need for an electronic control device capable of improving water resistance while increasing the amount of heat dissipation of the electronic control device.

The background technology of the present disclosure is disclosed in Korean Patent Registration No. 10-1610892 (registered on Apr. 4, 2016, entitled “ELECTRONIC CONTROL DEVICE OF VEHICLE USING POTTING LAYER AND MANUFACTURING METHOD THEREOF”).

### SUMMARY

Various embodiments are directed to an electronic control unit having improved water resistance.

An electronic control device according to the present disclosure includes a base part including a base plate, a panel part including a panel body disposed on a front of the base part and a panel body coupling hole communicating a first side of the panel body with a second side of the panel body, and a heat dissipation part including a heat dissipation body disposed on an upper portion of the base part to face the base plate and a heat dissipation coupling protrusion protruding from the heat dissipation body and inserted into the panel body coupling hole.

The panel part may include a panel body coupling unit that extends from the panel body and contacts the heat dissipation coupling protrusion.

The panel body coupling unit may include a panel body inner coupling portion extending from the heat dissipation body, disposed on a first side of the panel body coupling hole, and supporting the heat dissipation body, and a panel body outer coupling portion extending from the heat dissipation body, disposed on a second side of the panel body coupling hole, and supporting the heat dissipation body. The panel body coupling hole may be disposed between the inner coupling portion of the panel body and the outer coupling portion of the panel body.

The panel part may include a panel drain unit formed as a concave groove in the panel body and communicating with the panel body coupling hole.

The panel part may include a panel protrusion disposed to protrude from the panel body, and a panel protrusion hole disposed as a hole penetrating the panel protrusion.

An electronic control device according to the present disclosure includes a base part including a base plate, a panel part disposed on a front of the base plate, a heat dissipation part including a heat dissipation body disposed on an upper portion of the base part to face the base plate, a heat dissipation fin unit including a plurality of heat dissipation fins disposed on the heat dissipation body, and heat dissipation stoppers disposed between adjacent heat dissipation fins and disposed to protrude from the heat dissipation body.

A plurality of heat dissipation stoppers may be provided, and each of the heat dissipation stoppers may have a sawtooth shape.

The heat dissipation part may include a heat dissipation body concave unit formed concavely toward the base plate in the heat dissipation body, and the plurality of the heat dissipation fins may be disposed in the heat dissipation body concave unit.

The heat dissipation part may be disposed between the panel part and the heat dissipation fins and may include a heat dissipation body heat dissipation hole penetrating the heat dissipation body.

The heat dissipation part may include heat dissipation receiving units disposed on both sides of the heat dissipation fin unit to receive foreign substances.

The heat dissipation coupling protrusion may penetrate the panel body coupling hole.

The panel drain unit may communicate between the panel body outer coupling portion arranged on one side of the panel body coupling hole and the heat dissipation coupling protrusion.

The panel protrusion hole may be provided on the side of the panel protrusion.

The heat dissipation part may further include a heat dissipation drain unit that communicates with the heat dissipation body concave unit and discharges foreign substances received in the heat dissipation body concave unit.

The heat dissipation part may further include a heat dissipation path that is arranged in the heat dissipation body concave unit and serves as a path through which foreign substances received in the heat dissipation body concave unit move.

The heat dissipation path may include a heat dissipation path step disposed in the concave unit of the heat dissipation body and disposed to be stepped from the heat dissipation fin unit.

The electronic control device may further include a panel ventilation hole formed as a hole penetrating the panel part, and a heat dissipation fan arranged on the inside of the panel part and moving air outside the panel part to the inside of the panel part.

The electronic control device may further include a control part having a circuit board accommodated in the base part, an electronic component mounted on the circuit board, and a plug unit connected to the electronic component.

The electronic control device may further include a cover part disposed on the heat dissipation part and covering the heat dissipation body.

The electronic control device according to the present disclosure can improve water resistance performance. The electronic control device according to the present disclosure can improve heat dissipation performance.

### BRIEF DESCRIPTION OF THE DRAWINGS

FIG. 1 is a perspective view of an electronic control device according to an embodiment of the present disclosure from a first perspective.

FIG. 2 is an exploded perspective view of an electronic control device according to an embodiment of the present disclosure from a first perspective.

FIG. 3 is a perspective view of a part of an electronic control device according to an embodiment of the present disclosure from a second perspective.

FIG. 4 is a perspective view of a part of an electronic control device according to an embodiment of the present disclosure from a third perspective.

FIG. 5 is a perspective view of a cross-section of a part of an electronic control device according to an embodiment of the present disclosure from a third perspective.

FIG. 6 is an exploded perspective view of a cross-section of a part of an electronic control device according to an embodiment of the present disclosure from a third perspective.

FIG. 7 is a perspective view of an electronic control device according to an embodiment of the present disclosure from the rear.

FIG. 8 is a perspective view of a part of an electronic control device according to an embodiment of the present disclosure from the rear.

FIG. 9 is a perspective view of a cross-section of a part of an electronic control device according to an embodiment of the present disclosure.

FIG. 10 is a perspective view of a portion of an electronic control device according to an embodiment of the present disclosure from above.

### DETAILED DESCRIPTION

Hereinafter, an electronic control device according to the present disclosure is described in detail below with reference to the accompanying drawings through various exemplary embodiments. It should be considered that the thickness of each line or the size of each component in the drawings may be exaggeratedly illustrated for clarity and convenience of description.

In addition, terms to be described below have been defined by taking into consideration their functions in the present disclosure, and may be different depending on a user or operator's intention or practice. Accordingly, such terms should be interpreted based on the overall contents of this specification.

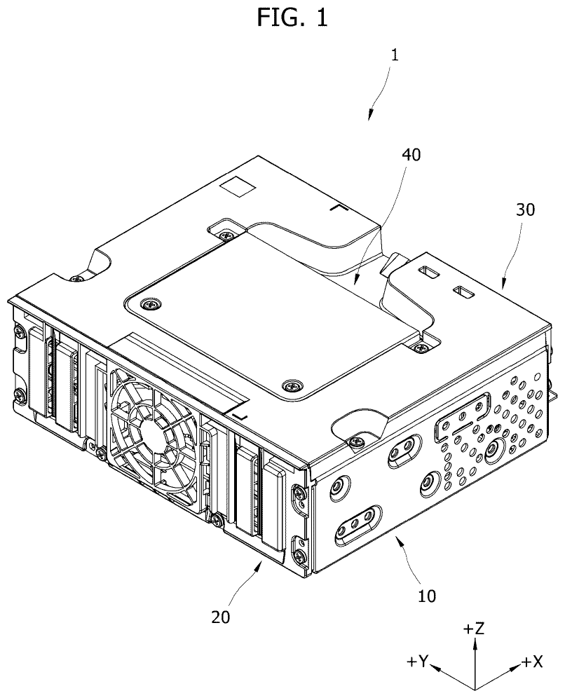

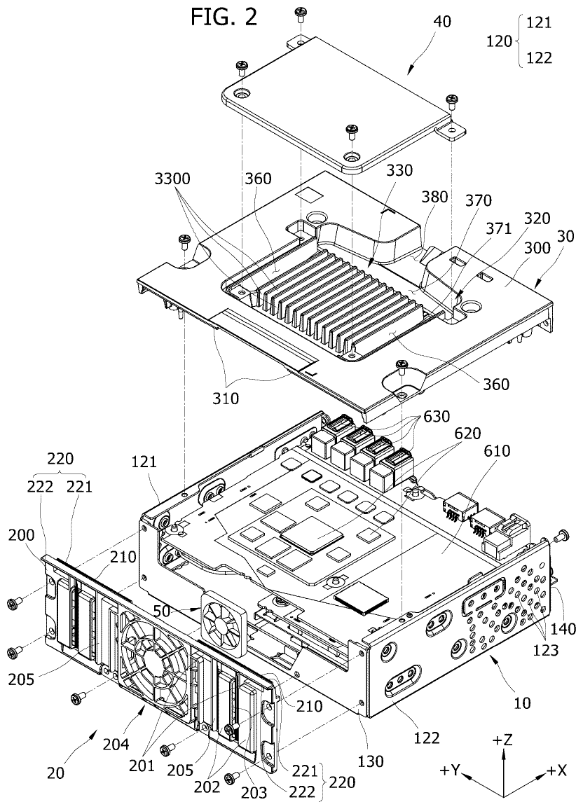

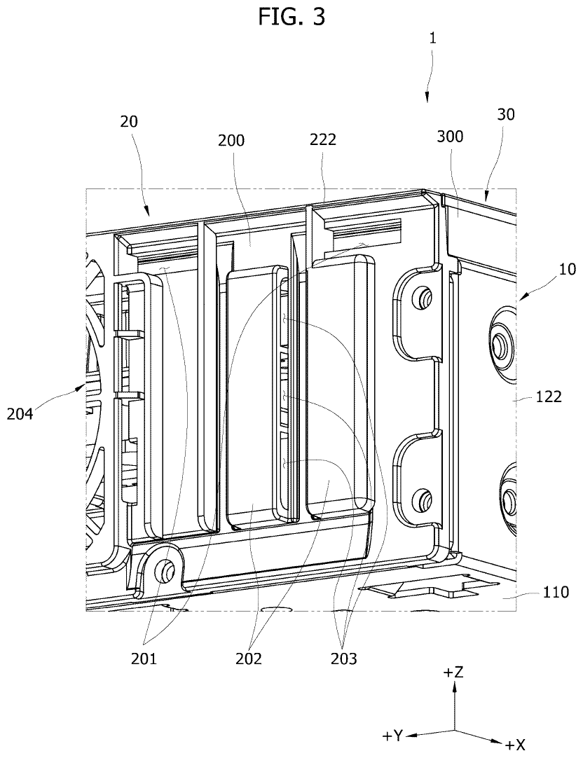

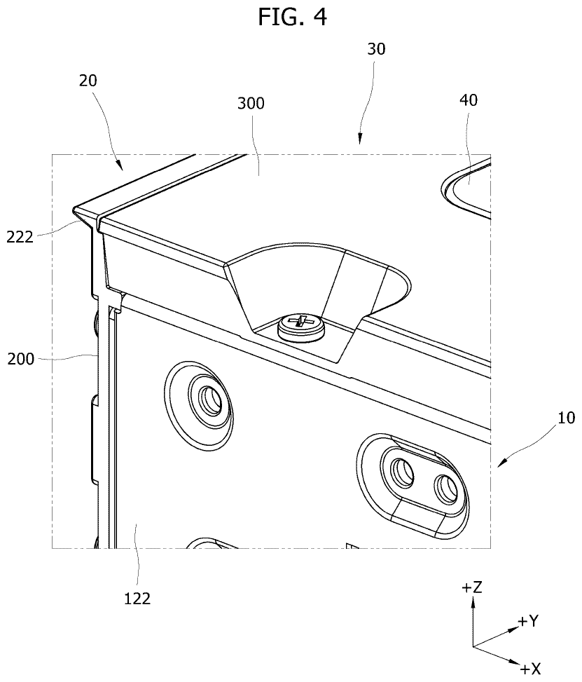

FIG. 1 is a perspective view of an electronic control device according to an embodiment of the present disclosure from a first perspective. FIG. 2 is an exploded perspective view of an electronic control device according to an embodiment of the present disclosure from a first perspective. FIG. 3 is a perspective view of a part of an electronic control device according to an embodiment of the present disclosure from a second perspective. FIG. 4 is a perspective view of a part of an electronic control device according to an embodiment of the present disclosure from a third perspective.

Referring to FIG. 1 to FIG. 4, the electronic control device 1 includes a base part 10, a panel part 20, a heat dissipation part 30, a cover part 40, a heat dissipation fan 50, and a control part 60. The base part 10, the panel part 20, the heat dissipation part 30, and/or the cover part 40 form the exterior of the electronic control device 1.

The base part 10 constitutes a lower surface (e.g., in the −Z-axis direction), a side surface (e.g., in the Y-axis direction), a portion of a front surface (e.g., in the −X-axis direction), and a portion of a rear surface (e.g., in the +X-axis direction) of the electronic control device 1.

The panel part 20 includes holes so that an outer side (e.g., in the −X-axis direction) and an inner side (e.g., in the +X-axis direction) of the panel part 20 communicate with each other. The holes are arranged at various locations at the panel part 20. Accordingly, air on the outside of the panel part 20 passes through the panel part 20 and move to the inside of the panel part 20. The panel part 20 is disposed on the front side (e.g., in the −X-axis direction) of the base part 10. The panel part 20 is coupled to the base part 10 and is coupled to the heat dissipation part 30.

The heat dissipation part 30 dissipates heat generated from the electronic control device 1. The heat dissipation part 30 is disposed on an upper side (e.g., in the +Z-axis direction) of the base part 10. The heat dissipation part 30 is coupled to the base part 10 and the panel part 20. Foreign substances, for example, water existing between the heat dissipation part 30 and the panel part 20 are discharged to the outside of the electronic control device 1 through the panel part 20.

The exterior of the electronic control device 1 is provided in a box shape by the base part 10, the panel part 20, and the heat dissipation part 30.

The cover part 40 is disposed on the heat dissipation part 30 to prevent foreign substances from entering the inside of the electronic control device 1. The cover part 40 comes into contact with the heat dissipation part 30 to perform a heat dissipation function.

The heat dissipation fan 50 is disposed in the panel part 20 to allow air to flow. According to an embodiment, the heat dissipation fan 50 is disposed on the inside of the panel part 20 (e.g., in the +X-axis direction) to allow air outside the electronic control device 1 to flow into the inside of the electronic control device 1. The air flowed by the heat dissipation fan 50 dissipates the heat generated in the electronic control device 1.

The control part 60 electronically controls a configuration of a vehicle. The control part 60 is disposed in a space surrounded by the base part 10, the panel part 20, and the heat dissipation part 30. The control part 60 includes a circuit board 610, electronic components 620, and plug units 630.

The circuit board 610 is disposed in the electronic control device 1, the electronic components 620 are disposed on the circuit board 610 and electrically and/or electronically connected to the circuit board 610, and the plug units 630 are electrically and/or electronically connected to the circuit board 610 and/or the electronic components 620. According to an embodiment, the plug unit 630 is disposed on the rear side (e.g., in the +X-axis direction) of the base part 10.

As the control part 60 operates, heat may be generated in the control part 60. The heat generated in the control part 60 may be released to the outside of the electronic control device 1 through the heat dissipation part 30.

Hereinafter, with reference to FIG. 1 to FIG. 4, the detailed configuration of the electronic control device 1 is described.

The base part 10 includes a base plate 110, side plates 120, a front plate 130, and a rear plate 140.

The base plate 110 is disposed parallel to a plane (e.g., X-Y plane). The base plate 110 constitutes a lower surface (e.g., in the −Z axis direction) of the electronic control device 1. The base plate 110 may be provided in an approximately square shape. The shape of the base plate 110 is not limited to the square shape, and the base plate 110 may be provided in various shapes.

The side plates 120 are disposed on the sides (e.g., in the Y-axis direction) of the base plate 110. The side plates 120 include a first side plate 121 and a second side plate 122. The first side plate 121 is disposed on one side (e.g., in the +Y-axis direction) of the base plate 110, and the second side plate 122 is disposed on the other side (e.g., in the −Y-axis direction) of the base plate 110.

According to an embodiment, the first side plate 121 and/or the second side plate 122 are/is disposed integrally with the base plate 110. The first side plate 121 and the second side plate 122 extend from the base plate 110 and are bent upward (e.g., in the +Z-axis direction). An angle formed by the first side plate 121 and/or the second side plate 122 and the base plate 110 may be approximately 70 degrees to 110 degrees. More specifically, the angle formed by the first side plate 121 and/or the second side plate 122 and the base plate 110 may be 90 degrees.

As the first side plate 121 and/or the second side plate 122 are/is disposed integrally with the base plate 110, foreign substances are prevented from entering the electronic control device 1.

The base part 10 further includes base holes 123 that penetrate the side plate 120. The base holes 123 are disposed at the first side plate 121 and/or the second side plate 122. As the base holes 123 are disposed in the base part 10, the inside and outside of the electronic control device 1 communicate with each other.

The front plate 130 is disposed on the front side (e.g., in the −X-axis direction) of the base plate 110.

According to an embodiment, the front plate 130 is disposed integrally with the base plate 110. The front plate 130 extends from the base plate 110 and is bent upward (e.g., in the +Z-axis direction). An angle formed by the front plate 130 and the base plate 110 may be approximately 70 degrees to 110 degrees. More specifically, the angle formed by the front plate 130 and the base plate 110 is approximately 90 degrees.

The front plate 130 is in contact with the side plates 120. According to an embodiment, the front plate 130 is coupled to the side plates 120. More specifically, the front plate 130 is bolted to the first side plate 121 and/or the second side plate 122.

A waterproofing member (not shown) may be disposed between the front plate 130 and the side plates 120. Accordingly, the water resistance of the electronic control device 1 can be improved.

The rear plate 140 is disposed on the rear side (e.g., in the +X-axis direction) of the base plate 110. In an embodiment, the rear plate 140 is disposed integrally with the base plate 110. The rear plate 140 extends from the base plate 110 and is bent upward (e.g., in the +Z-axis direction). An angle formed by the rear plate 140 and the base plate 110 may be approximately 70 degrees to 110 degrees. More specifically, the angle formed by the rear plate 140 and the base plate 110 is approximately 90 degrees.

The rear plate 140 is in contact with the side plate 120. According to an embodiment, the rear plate 140 is coupled to the side plates 120. More specifically, the rear plate 140 is bolted to the first side plate 121 and/or the second side plate 122.

A waterproofing member (not shown) may be disposed between the rear plate 140 and the side plate 120. Accordingly, the water resistance of the electronic control device 1 can be improved.

The panel part 20 is disposed in front (e.g., in the −X-axis direction) of the base plate 110. According to an embodiment, the panel part 20 is coupled with the base plate 110 and/or the front plate 130.

The panel part 20 includes a panel body 200, panel body coupling holes 210, and panel body coupling units 220.

The panel body 200 may be provided in an approximately square shape. The shape of the panel body 200 is not limited to the square shape, and the panel body 200 may be provided in various shapes.

The panel body coupling holes 210 are disposed in the panel body 200. According to an embodiment, the panel body coupling holes 210 are disposed on the upper side (e.g., in the +Z-axis direction) of the panel body 200. The panel body coupling holes 210 communicate one side (e.g., in the +Z-axis direction) and the other side (e.g., in the −X-axis direction) of the panel body 200. The heat dissipation part 30 is inserted into the panel body coupling holes 210. According to an embodiment, the heat dissipation body 300 of the heat dissipation part 30 is inserted into the panel body coupling holes 210. More specifically, the heat dissipation coupling protrusions 310 of the heat dissipation body 300 are inserted into the panel body coupling holes 210.

As the heat dissipation coupling protrusions 310 of the heat dissipation body 300 are inserted into the panel body coupling holes 210, foreign substances between the panel body 200 and the heat dissipation body 300 can be discharged to the outside of the electronic control device 1 through the panel body coupling holes 210.

The panel body coupling units 220 are disposed on the panel body 200. According to an embodiment, the panel body coupling units 220 are disposed on the upper side (e.g., in the +Z-axis direction) of the panel body 200. The panel body coupling units 220 are coupled to the heat dissipation body 300 of the heat dissipation part 30. According to an embodiment, the heat dissipation coupling protrusions 310 of the heat dissipation body 300 are inserted into the panel body coupling units 220.

The panel body coupling unit 220 includes a panel body inner coupling portion 221 and a panel body outer coupling portion 222.

The panel body inner coupling portion 221 and/or the panel body outer coupling portion 222 extend along one axis (e.g., Y-axis). The panel body inner coupling portion 221 is disposed closer to the rear plate 140 than the panel body outer coupling portion 222. According to an embodiment, the panel body inner coupling portion 221 is disposed in the +X-axis direction than the panel body outer coupling portion 222.

The panel body coupling holes 210 are disposed between the panel body inner coupling portions 221 and the panel body outer coupling portions 222. As the heat dissipation coupling protrusions 310 of the heat dissipation body 300 are inserted into the panel body coupling holes 210 disposed between the panel body inner coupling portions 221 and the panel body outer coupling portions 222, when foreign substances existing in the heat dissipation part 30 move between the panel part 20 and the heat dissipation part 30, the foreign substances may move along the space between the heat dissipation body 300 and the panel body outer coupling portion 222, may move between the heat dissipation coupling protrusions 310 and the panel body outer coupling portions 222, and may be discharged to the outside of the electronic control device 1 through panel drain units 201 that is connected to the panel body coupling holes 210.

In this way, as the panel body coupling holes 210 are disposed between the panel body inner coupling portions 221 and the panel body outer coupling portions 222 and the heat dissipation coupling protrusions 310 are inserted into the panel body coupling holes 210, the foreign substances present in the heat dissipation part 30 can be discharged to the outside of the electronic control device 1 through the panel body coupling holes 210 and the panel drain units 201 without being introduced into the electronic control device 1.

The panel drain units 201, panel protrusions 202, panel protrusion holes 203, a panel ventilation hole 204, and panel ribs 205 are disposed on the panel body 200.

The panel drain units 201 are provided as holes penetrating the panel body 200. According to an embodiment, the panel drain units 201 are disposed on (e.g., in the +Z-axis direction) the center of the panel body 200 in a height direction (e.g., in the Z-axis direction).

The panel drain units 201 are provided as holes penetrating one side (e.g., in the −X-axis direction) and the other side (e.g., in the +Z-axis direction) of the panel body 200. A plurality of panel drain units 201 may be provided.

The panel drain units 201 are disposed to communicate with the panel body coupling holes 210. In this way, as the panel drain units 201 communicate with the panel body coupling holes 210, the foreign substances (e.g., water) existing on the upper side (e.g., in the +Z-axis direction) of the electronic control device 1 can be discharged to the outside of the electronic control device 1 through the panel body coupling holes 210 and the panel drain units 201.

The panel protrusions 202 are disposed to protrude from the panel body 200. According to an embodiment, the panel protrusions 202 are provided to protrude outwardly (e.g., in the −X-axis direction) from the panel body 200.

The panel protrusion holes 203 are provided as holes penetrating the panel protrusions 202. As the panel protrusion holes 203 are provided as the holes penetrating the panel protrusions 202, the exterior and interior of the electronic control device 1 communicated with each other through the panel protrusion holes 203.

The panel protrusion holes 203 are disposed on the sides (e.g., in the Y-axis direction) of the panel protrusions 202. As the panel protrusion holes 203 are disposed on the sides of the panel protrusions 202, the probability of foreign substances entering from the outside of the electronic control device 1 can be reduced, compared to when the panel protrusion holes 203 are disposed on the front (e.g., in the −X-axis direction) of the panel protrusions 202.

The panel ventilation hole 204 is disposed in the panel body 200. The panel ventilation hole 204 is provided as a hole penetrating the panel body 200. The panel ventilation hole 204 is provided in a grid shape. A filter (not shown) may be disposed in the panel ventilation hole 204. As the filter is disposed in the panel ventilation hole 204, foreign substances may be filtered when air is introduced from the outside of the electronic control device 1 into the inside of the electronic control device 1.

The heat dissipation fan 50 is disposed in the panel ventilation hole 204. By driving the heat dissipation fan 50, air may flow from the outside of the electronic control device 1 to the inside of the electronic control device 1. According to one embodiment, the heat dissipation fan 50 is disposed inside the electronic control device 1. The heat dissipation fan 50 is disposed on one side (e.g., in the +X-axis direction) of the panel ventilation hole 204. The heat dissipation fan 50 is disposed between the panel body 200 and the rear plate 140.

The panel ribs 205 are disposed to protrude from the panel body 200. The panel ribs 205 protrude from the panel body 200 to one side (e.g., in the −X-axis direction) and are disposed adjacent to the panel drain units 201. As the panel ribs 205 are disposed adjacent to the panel drain units 201, the panel ribs 205 can induce movement of foreign substances discharged from the panel drain units 201.

The panel ribs 205 are disposed to face the panel protrusion holes 203. As the panel ribs 205 are disposed to face the panel protrusion holes 203, the probability of foreign substances entering the panel protrusion holes 203 can be reduced.

The heat dissipation part 30 is disposed on the upper side (e.g., in the +Z-axis direction) of the base part 10. The heat dissipation part 30 is coupled to the base part 10 and the panel part 20.

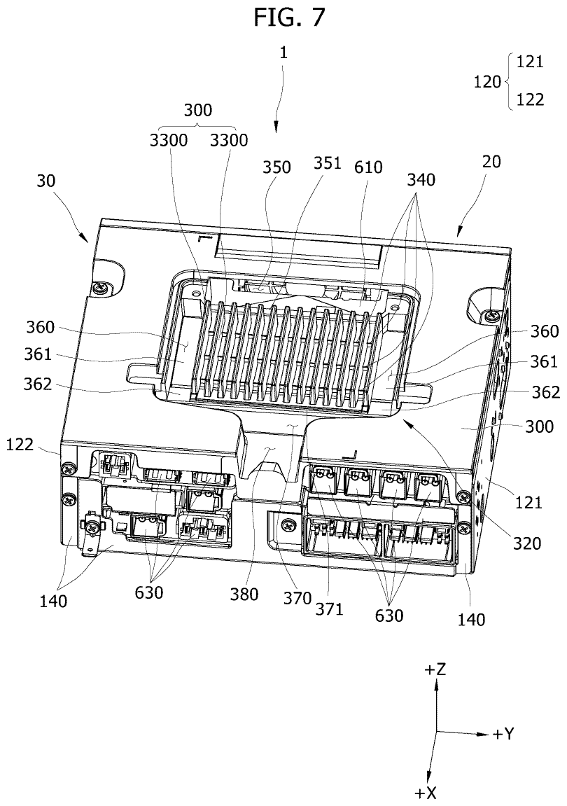

The heat dissipation part 30 includes the heat dissipation body 300, the heat dissipation coupling protrusions 310, the heat dissipation body concave unit 320, the heat dissipation fin unit 330, heat dissipation stoppers (e.g., heat dissipation stoppers 340 of FIG. 7), a heat dissipation body heat dissipation hole (e.g., the heat dissipation body heat dissipation hole 350 of FIG. 7), heat dissipation receiving unit 360, a heat dissipation path 370, and a heat dissipation drain unit 380.

The heat dissipation body 300 is disposed to face the base plate 110. The heat dissipation body 300 may be provided in an approximately square shape. The shape of the heat dissipation body 300 is not limited to square and the heat dissipation body 300 may be provided in various shapes.

The heat dissipation coupling protrusions 310 are disposed to protrude from the heat dissipation body 300. The heat dissipation coupling protrusions 310 are disposed at the lower portion (e.g., in the −Z-axis direction) of the heat dissipation body 300. The heat dissipation coupling protrusions 310 extend along one direction (e.g., in the Y-axis direction).

The heat dissipation coupling protrusions 310 are inserted into the panel part 20. According to an embodiment, the heat dissipation coupling protrusions 310 are inserted into the panel body coupling holes 210. The heat dissipation coupling protrusions 310 penetrate the panel body coupling holes 210. The panel body coupling holes 210 are disposed between the panel body inner coupling portion 221 and the panel body outer coupling portion 222.

In this way, as the heat dissipation coupling protrusions 310 are disposed to penetrate the panel body coupling holes 210 disposed between the panel body inner coupling portion 221 and the panel body outer coupling portion 222, foreign substances existing between the heat dissipation body 300 and the panel body 200 move to the panel body coupling holes 210 through the heat dissipation coupling protrusions 310 and the panel body outer coupling portion 222, and move to the panel drain parts 201 connected to the panel body coupling holes 210 to be discharged to the outside of the electronic control device 1.

The heat dissipation body concave unit 320 is provided as a concave space in the heat dissipation body 300. According to an embodiment, the heat dissipation body concave unit 320 is provided as a concave recess facing downward (e.g., in the −Z-axis direction) on an upper surface (e.g., in the +Z-axis direction) of the heat dissipation body 300.

The heat dissipation fin unit 330, the heat dissipation body heat dissipation hole 350, the heat dissipation receiving units 360, the heat dissipation path 370, and the heat dissipation drain unit 380 are disposed in the heat dissipation body concave unit 320.

The heat dissipation fin unit 330 is disposed in the heat dissipation body concave unit 320. The heat dissipation fin unit 330 dissipates heat generated in the electronic control device 1 to the outside of the electronic control device 1. The heat dissipation fin unit 330 includes heat dissipation fins 3300.

A plurality of heat dissipation fins 3300 are provided. The heat dissipation fins 3300 are provided to protrude from the heat dissipation body 300. According to an embodiment, the heat dissipation fins 3300 are disposed to extend along one direction (e.g., X-axis direction). The plurality of heat dissipation fins 3300 are disposed along another direction (e.g., Y-axis direction).

In this way, as the heat dissipation fins 3300 extend along one direction (e.g., X-axis direction) and are disposed along another direction (e.g., Y-axis direction), air introduced into the electronic control device 1 from the panel ventilation unit 240 can flow along one direction (e.g., X-axis direction) and move between the plurality of heat dissipation fins 3300. Furthermore, it is possible to reduce the resistance of air flow that may occur between the plurality of heat dissipation fins 3300 and increase the flow rate of air in contact with the heat dissipation fins 3300.

The heat dissipation stoppers 340 are disposed between the plurality of heat dissipation fins 3300. The heat dissipation stoppers 340 is described later with reference to FIG. 7. The heat dissipation body heat dissipation hole 350 is provided as a hole penetrating the heat dissipation body 300. The heat dissipation body heat dissipation hole 350 is described later with reference to FIG. 7.

The heat dissipation receiving units 360 are disposed adjacent to the heat dissipation fin unit 330. The heat dissipation receiving units 360 are provided as spaces capable of receiving foreign substances flowing in from the outside of the electronic control device 1. According to an embodiment, the heat dissipation receiving units 360 are respectively disposed on both sides (e.g., in the Y-axis direction) of the heat dissipation fin part 330.

Because the heat dissipation receiving units 360 are respectively disposed on both sides of the heat dissipation fin part 330, the probability of foreign substances flowing into the electronic control device 1 can be reduced. The heat dissipation receiving unit 360 includes a heat dissipation receiving reservoir 361 and a heat dissipation receiving guide 362. A description of the heat dissipation receiving reservoir 361 and the heat dissipation receiving guide 362 are described later together with the description of FIG. 7.

The heat dissipation path 370 is disposed in the heat dissipation body concave unit 320. The heat dissipation path 370 is provided as a path through which air or foreign substances move. The heat dissipation path 370 communicated with between the heat dissipation fins 3300, the heat dissipation receiving units 360, and the heat dissipation drain unit 380.

The heat dissipation path 370 is formed to be inclined so that movement of foreign substances existing in the heat dissipation path 370 can be induced. According to an embodiment, the foreign substances existing in the heat dissipation path 370 move to the heat dissipation drain unit 380. The heat dissipation path 370 is disposed to be inclined in the −Z-axis direction as it goes in the +X-axis direction.

A heat dissipation path step 371 is disposed between the heat dissipation path 370 and the plurality of heat dissipation fins 3300. The heat dissipation path step 371 forms a step between the heat dissipation path 370 and the heat dissipation fins 3300. Accordingly, foreign substances existing in the heat dissipation path 370 can be prevented from moving to the heat dissipation fin 3300 by the heat dissipation path step 371.

The heat dissipation drain unit 380 is disposed on one side (e.g., in the +X-axis direction) of the heat dissipation path 370. The heat dissipation drain unit 380 communicates with the heat dissipation path 370. As the heat dissipation drain unit 380 communicates with the heat dissipation path 370, the foreign substances existing in the heat dissipation path 370 can be discharged to the outside of the electronic control device 1 through the heat dissipation drain unit 380.

The heat dissipation drain unit 380 is disposed to be inclined. According to an embodiment, the heat dissipation drain unit 380 is disposed to be inclined in the −Z-axis direction as goes in the +X-axis direction. Accordingly, the foreign substances can be smoothly discharged through the heat dissipation drain unit 380.

The cover part 40 is disposed on the upper side (e.g., in the +Z-axis direction) of the heat dissipation body concave unit 320. According to an embodiment, the cover part 40 is disposed to cover the heat dissipation body concave unit 320. Because the cover part 40 is disposed on the upper side of the heat dissipation body concave unit 320, foreign substances can be prevented from directly flowing into the heat dissipation fin unit 330. In addition, because the cover part 40 is disposed on the upper side of the heat dissipation body concave unit 320, foreign substances can be prevented from moving directly to the heat dissipation body heat dissipation hole 350 formed in the heat dissipation body 300.

In this way, because the cover part 40 is disposed on the upper side of the heat dissipation body concave unit 320, the probability of foreign substances entering the inside of the electronic control device 1 can be reduced.

The heat dissipation fan 50 is disposed adjacent to the panel ventilation hole 204 to allow air outside the electronic control device 1 to flow into the inside of the electronic control device 1. Accordingly, the flow rate of air flowing into the electronic control device 1 increases, so that the heat dissipation performance of the electronic control device 1 can be improved.

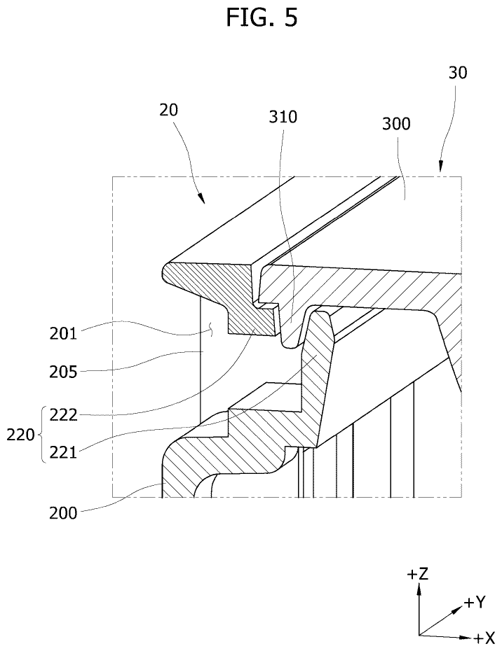

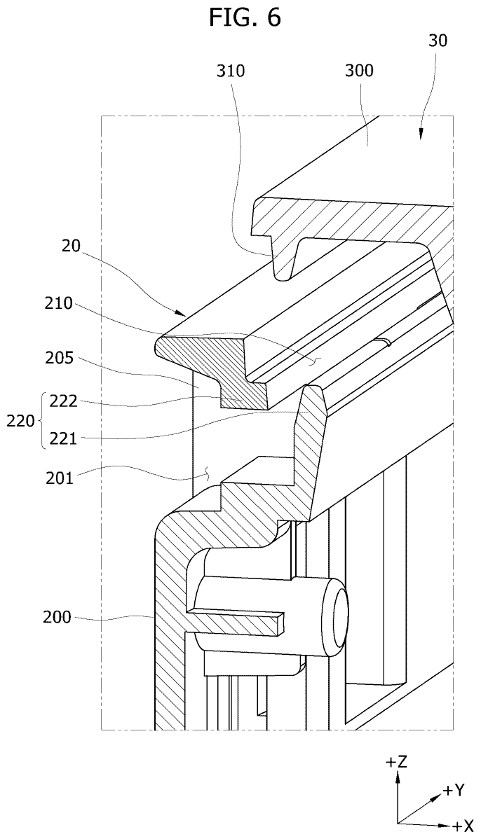

FIG. 5 is a perspective view of a cross-section of a part of an electronic control device according to an embodiment of the present disclosure from a third perspective. FIG. 6 is an exploded perspective view of a cross-section of the part of the electronic control device according to an embodiment of the present disclosure from a third perspective.

Referring to FIG. 5 and FIG. 6, the arrangement structure of the panel part 20 and the heat dissipation part 30 is described.

The panel body coupling unit 220 includes the panel body inner coupling portion 221 and the panel body outer coupling portion 222. The panel body coupling holes 210 are disposed between the panel body inner coupling portion 221 and the panel body outer coupling portion 222.

The heat dissipation coupling protrusions 310 are inserted into the panel body coupling holes 210. According to an embodiment, the heat dissipation coupling protrusions 310 are disposed to penetrate the panel body coupling holes 210.

In this way, as the heat dissipation coupling protrusions 310 are inserted into the panel body coupling holes 210 disposed between the panel body inner coupling portion 221 and the panel body outer coupling portion 222, foreign substances existing between the panel body 200 and the heat dissipation body 300 may move between the panel body outer coupling portion 222 and the heat dissipation coupling protrusions 310, and may not move between the panel body inner coupling portion 221 and the heat dissipation coupling protrusions 310.

The foreign substances existing between the panel body outer coupling portion 222 and the heat dissipation coupling protrusions 310 can be discharged to the outside of the electronic control device 1 through the panel drain units 201. The panel ribs 205 disposed on the side of the panel drain units 201 can guide the movement of foreign substances discharged from the electronic control device 1.

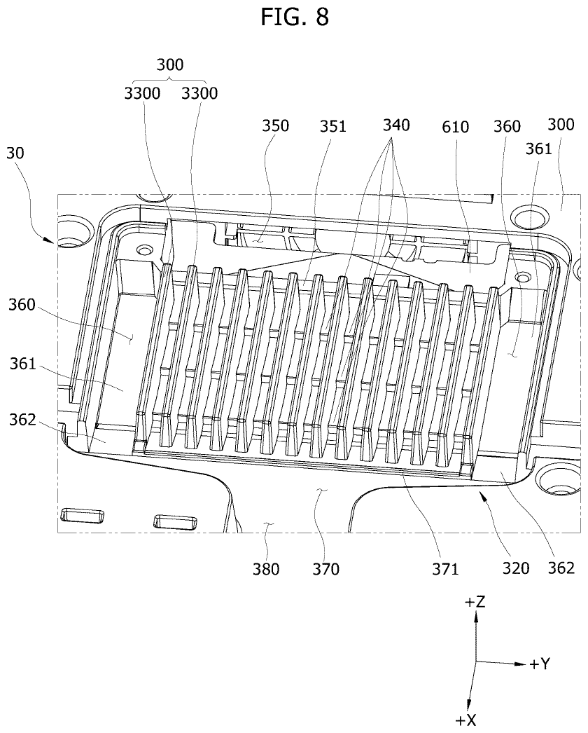

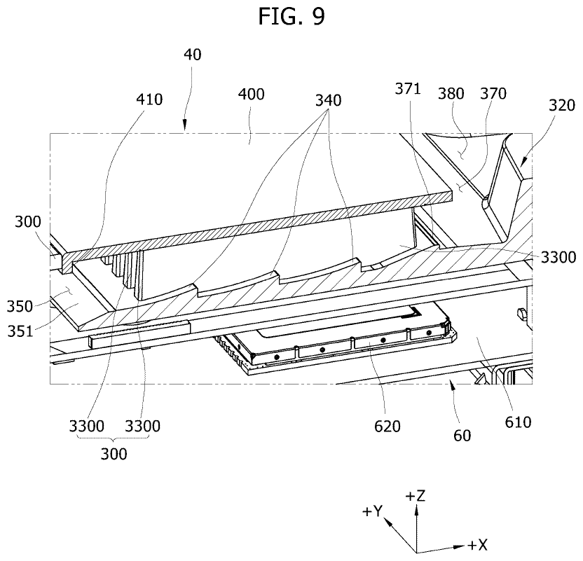

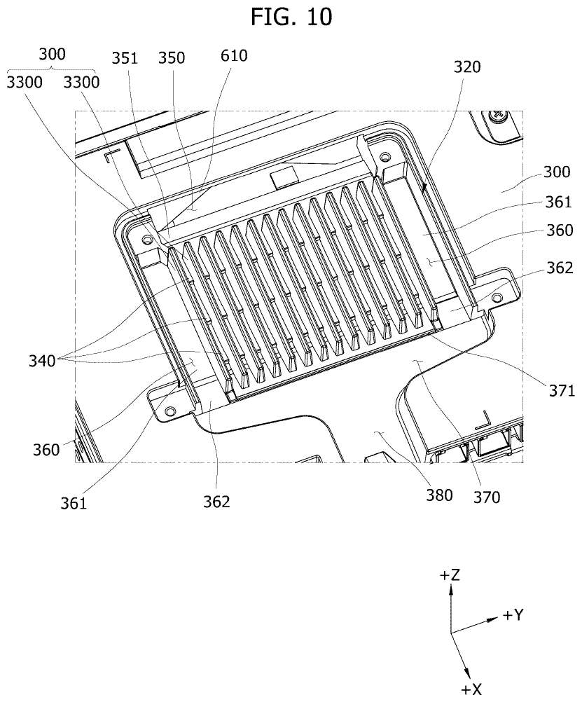

FIG. 7 is a perspective view of an electronic control device according to an embodiment of the present disclosure from the rear. FIG. 8 is a perspective view of a part of the electronic control device according to an embodiment of the present disclosure from the rear. FIG. 9 is a perspective view of a cross-section of a part of the electronic control device according to an embodiment of the present disclosure. FIG. 10 is a perspective view of a part of the electronic control device according to an embodiment of the present disclosure from above.

Referring to FIG. 7 to FIG. 10, the detailed configuration of the heat dissipation part 30 and the cover part 40 is described.

Heat dissipation stoppers 340 are disposed between the plurality of heat dissipation fins 3300 of the heat dissipation fin unit 330. The heat dissipation stoppers 340 are disposed between adjacent heat dissipation fins 3300 to limit foreign substances from moving in one direction (e.g., in the −X-axis direction). A plurality of heat dissipation stoppers 340 may be provided.

The heat dissipation stoppers 340 may be provided in various shapes such as saw teeth and steps. According to an embodiment, the heat dissipation stoppers 340 repeatedly rapidly increase and gradually decrease in height (e.g., +Z-axis direction) while moving in the −X-axis direction. In this way, as the height rapidly increases while moving in the −X-axis direction, the movement of foreign substances in the −X-axis direction can be restricted.

The heat dissipation body heat dissipation hole 350 configured as a hole penetrating the heat dissipation body 300 is disposed on one side of the heat dissipation fin unit 330. According to an embodiment, the heat dissipation body heat dissipation hole 350 is disposed between the front plate 130 and the heat dissipation fin unit 330. More specifically, the heat dissipation body heat dissipation hole 350 is disposed in the −X-axis direction of the heat dissipation fin unit 330.

As the heat dissipation body heat dissipation hole 350 is disposed in the heat dissipation body 300, flowing air existing in the panel ventilation holes 204 can pass through the heat dissipation body heat dissipation hole 350 and move to the heat dissipation fin unit 330 by the heat dissipation fan 50. Accordingly, the air flow rate in contact with the heat dissipation fin unit 330 increases, so that the heat dissipation performance of the electronic control device 1 can be improved.

A heat dissipation body guide 351 is disposed to be inclined in the heat dissipation body heat dissipation hole 350. The heat dissipation body guide 351 is disposed to be inclined in the −Z-axis direction as goes toward the −X-axis. As the heat dissipation body guide 351 is disposed to be inclined in this way, the flow rate of air flowing from the panel ventilation unit 240 to the heat dissipation fin unit 330 can increase. Accordingly, the heat dissipation performance of the electronic control device 1 can be improved.

The heat dissipation receiving unit 360 includes heat dissipation receiving reservoirs 361 and a heat dissipation receiving guide 362.

The heat dissipation receiving reservoirs 361 are disposed on both sides (e.g., in the Y-axis direction) of the heat dissipation fin unit 330. The heat dissipation receiving reservoirs 361 are provided as spaces in which foreign substances are received. As the heat dissipation receiving reservoirs 361 are disposed on both sides of the heat dissipation fin unit 330, foreign the substances that cannot move from the radiant flow path 370 to the heat dissipation drain unit 380 may be received in the heat dissipation receiving reservoirs 361.

The heat dissipation guides 362 communicate the heat dissipation reservoirs 361 with the heat dissipation path 370. The heat dissipation guides 362 are disposed to be inclined. According to an embodiment, the heat dissipation guides 362 are disposed to be inclined in the −Z-axis direction as moves in the −X-axis direction. In this way, as the heat dissipation guides 362 are disposed to be inclined, foreign substances that cannot be discharged from the heat dissipation path 370 to the heat dissipation drain unit 380 can move to the heat dissipation reservoirs 361 through the heat dissipation guides 362.

The cover part 40 includes a cover body 400 and a cover body protrusion 410.

The cover body 400 is disposed to cover the heat dissipation body concave unit 320 to prevent foreign substances from moving to the heat dissipation fin unit 330 and the heat dissipation body heat dissipation hole 350.

The cover body protrusion 410 is disposed to protrude from the cover body 400. According to an embodiment, the cover body protrusion 410 is configured to be bent from one end (e.g., in the −X-axis direction) of the cover body 400 toward the lower side (e.g., in the −Z-axis direction) so as to protrude from the cover body 400.

The cover body protrusion 410 comes into contact with the heat dissipation body 300. A length of the cover body protrusion 410 that protrudes is longer than a thickness of the cover body 400. As the cover body protrusion 410 longer than the thickness of the cover body 400 comes into contact with the heat dissipation body 300, a contact area between the heat dissipation body 300 and the cover body 400 can be increased. Accordingly, the probability of foreign substances entering the electronic control device 1 can be reduced.

Although exemplary embodiments of the disclosure have been disclosed for illustrative purposes, those skilled in the art will appreciate that various modifications, additions and substitutions are possible, without departing from the scope and spirit of the disclosure as defined in the accompanying claims. Thus, the true technical scope of the disclosure should be defined by the following claims.

What is claimed is:

1. An electronic control device comprising:
a base part comprising a base plate;
a panel part comprising a panel body disposed on a front of the base part and a panel body coupling hole communicating a first side of the panel body with a second side of the panel body; and
a heat dissipation part comprising a heat dissipation body disposed on an upper portion of the base part to face the base plate and a heat dissipation coupling protrusion protruding from the heat dissipation body and inserted into the panel body coupling hole.

2. The electronic control device as claimed in claim 1, wherein the panel part comprises a panel body coupling unit that extends from the panel body and contacts the heat dissipation coupling protrusion.

3. The electronic control device as claimed in claim 2,
wherein the panel body coupling unit comprises:
a panel body inner coupling portion extending from the heat dissipation body, disposed on a first side of the panel body coupling hole, and supporting the heat dissipation body; and
a panel body outer coupling portion extending from the heat dissipation body, disposed on a second side of the panel body coupling hole, and supporting the heat dissipation body, and
wherein the panel body coupling hole is disposed between the inner coupling portion of the panel body and the outer coupling portion of the panel body.

4. The electronic control device as claimed in claim 1, wherein the panel part comprises a panel drain unit formed as a concave groove in the panel body and communicating with the panel body coupling hole.

5. The electronic control device as claimed in claim 1, wherein the panel part comprises:
a panel protrusion disposed to protrude from the panel body; and
a panel protrusion hole penetrating the panel protrusion.

6. An electronic control device comprising:
a base part comprising a base plate;
a panel part disposed on a front of the base plate;
a heat dissipation part comprising a heat dissipation body disposed on an upper portion of the base part to face the base plate, a heat dissipation fin unit comprising a plurality of heat dissipation fins disposed on the heat dissipation body, and heat dissipation stoppers disposed between adjacent heat dissipation fins and disposed to protrude from the heat dissipation body.

7. The electronic control device as claimed in claim 6, wherein each of the heat dissipation stoppers has a sawtooth shape.

8. The electronic control device as claimed in claim 6,
wherein the heat dissipation part comprises a heat dissipation body concave unit formed concavely toward the base plate in the heat dissipation body, and
wherein the plurality of the heat dissipation fins are disposed in the heat dissipation body concave unit.

9. The electronic control device as claimed in claim 6, wherein the heat dissipation part is disposed between the panel part and the heat dissipation fins and comprises a heat dissipation body heat dissipation hole penetrating the heat dissipation body.

10. The electronic control device as claimed in claim 6, wherein the heat dissipation part comprises heat dissipation receiving units disposed on both sides of the heat dissipation fin unit to receive foreign substances.
